(19) United States
(12) Patent Application Publication
(10) Pub. No.: US 2005/0215062 A1
(43) Pub. Date: Sep. 29, 2005

(54) Method of manufacturing semiconductor device

(76) Inventors: Osamu Miyagawa, Yokohama-shi (JP); Masaki Narita, Yokohama-shi (JP); Tokuhisa Ohiwa, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/079,098

(22) Filed: Mar. 15, 2005

(30) Foreign Application Priority Data
Mar. 16, 2004 (JP) 2004-074496

(51) Int. Cl. H01L 21/00

(52) U.S. Cl. 438/706; 438/722

(57) ABSTRACT

A method of manufacturing a semiconductor device involves etching a film of a metal oxide formed above a semiconductor substrate, by using an etching gas. The etching gas includes a reducing gas which is capable of reducing the metal oxide and is non-reactive with the metal, and a reactive gas which is capable of etching the metal.

### CROSS-REFERENCE TO RELATED APPLICATIONS

This application is based upon and claims the benefit of priority from prior Japanese Patent Application No. 2004-074496, filed Mar. 16, 2004, the entire contents of which are incorporated herein by reference.

### BACKGROUND OF THE INVENTION

1. Field of the Invention

The present invention relates to a method of manufacturing a semiconductor device, and more particularly to a method of manufacturing a semiconductor device, which comprises etching an oxide of a metal having a strong bonding strength with oxygen.

2. Description of the Related Art

With the scale down of semiconductor elements, so-called high-k materials exhibiting a high dielectric constant have been required as a gate material of transistors. Metal oxides represented by alumina have a relatively high dielectric constant, and thus attract attention as high-k materials.

Although alumina can be etched by sputter etching utilizing physical sputtering effect exerted by accelerated ions, nonvolatile sputtered materials generated upon etching deposit on the surface of alumina, lowering etching rate of alumina.

Under the circumstances, for etching alumina, reactive ion etching (RIE) using a chlorine-based reactive gas (for example, Cl₂ or a mixed gas of Cl₂ with BCl₃), which avoids substantial influence on the etching rate of alumina due to the etching reaction products formed, has become employed. The mixed gas of Cl₂ with BCl₃ is disclosed in Japanese Patent Application Disclosure (KOKAI) No. 2001-15479. RIE is one of dry etching techniques like sputter etching and performs anisotropic etching.

Generally, to conduct RIE, a semiconductor substrate having a target film is placed on a cathode in a vacuum chamber. A high-frequency voltage is applied to the cathode to generate electric discharge in the vacuum chamber. When a reactive gas is introduced into the vacuum chamber, the reactive gas turns into a plasma, and is dissociated into active reactive ion species and electrons. These active reactive ion species are directed toward the substrate on the cathode perpendicularly thereto and impinge on the target film, thereby etching the target film.

As described above, RIE performs the etching through a chemical reaction caused by the energy derived from the impingement, upon the target film, of the active reactive ion species from the reactive gas. In this case, since the active reactive ion species impinge perpendicularly on the target film, anisotropic etching can be performed.

When an alumina film is etched by RIE using the chlorine-based reactive gas noted above, the reaction products can be removed from the vacuum chamber by evacuation, since the reaction products are volatile. Accordingly, the reaction products do not deposit on the alumina film and hence the etching rate of the alumina film is not lowered.

However, since alumina, which is aluminum oxide, is strong in bonding strength between aluminum and oxygen, even if the aforementioned chlorine-based reactive gas is employed, the etching rate itself by RIE is not sufficiently high. As a result, during etching an alumina film using the chlorine-based reactive gas, exposed portions of a film or films other than the alumina film are caused to expose to the plasma of the chlorine-based reactive gas for a long period of time, thus possibly deteriorating the other film or films.

Meanwhile, when BCl₃ is employed singly in RIE, active boron ion species and active chlorine ion species are generated in the plasma. The active boron ion species, being reductive in nature, reduce the surface of alumina to aluminum, and the active chlorine ion species etch the aluminum. However, in reducing alumina by the active boron ion species, boron oxide which is non-volatile, is also formed and deposits as particles on the surface of the substrate being etched.

### BRIEF SUMMARY OF THE INVENTION

According to an aspect of the present invention, there is provided a method of manufacturing a semiconductor device, which comprises etching a film of a metal oxide comprising a metal bonded with oxygen, formed above a semiconductor substrate, by using an etching gas, the etching gas comprising a reducing gas which is capable of reducing the metal oxide and is non-reactive with the metal, and a reactive gas which is capable of etching the metal.

### BRIEF DESCRIPTION OF THE SEVERAL VIEWS OF THE DRAWING

FIGS. 1A to 1F are cross-sectional views sequentially illustrating an example of forming gate electrode structures of a NAND type non-volatile memory according to one embodiment of the present invention;

FIGS. 2A to 2C are cross-sectional views sequentially illustrating procedures for etching an alumina film; and

FIGS. 3A and 3B are graphs respectively showing the etched depths measured on an alumina film etched according to the procedures illustrated in FIGS. 2A to 2C, by using chlorine gas alone and by using a mixture of methane gas with chlorine gas, respectively.

### DETAILED DESCRIPTION OF THE INVENTION

A method of manufacturing a semiconductor device according to one embodiment of the present invention comprises etching a film of a metal oxide comprising a metal bonded with oxygen, formed above a semiconductor substrate, by using an etching gas. The etching gas comprises both a reducing gas which is capable of reducing the metal oxide and is non-reactive with the metal, and a reactive gas which is capable of etching the metal.

In one embodiment of the present invention, the etching of the metal oxide film is performed by RIE. For example, the RIE can be performed using an ordinary etching apparatus comprising a vacuum chamber (etching chamber) equipped with an etching gas inlet conduit and an exhaust gas outlet conduit. A cathode is installed in the chamber. The etching apparatus has also a high-frequency power source. A semiconductor substrate having a metal oxide film is mounted on the cathode and then a high-frequency voltage is applied to the cathode to generate electric discharge in the vacuum chamber. When an etching gas is introduced into the vacuum chamber, the etching gas turns into a plasma, and is dissociated into active ion species and electrons. The active ion species are directed toward the substrate perpendicularly thereto, etching the metal oxide film as explained in detail below.

In one embodiment of the present invention, the metal oxide is an oxide of a metal exhibiting a high bonding strength with oxygen, and may be a metal oxide whose metal can be etched at a higher rate than the metal oxide itself by the reactive gas. Examples of such a metal oxide include alumina (Al₂O₃), hafnium oxide (HfO₃), aluminum-hafnium oxide (AlHfOₓ), and hafnium-silicon oxide (HfSiOₓ). These metal oxides are expected to be useful as a high-k material. These metal oxides can be deposited on a substrate by CVD (chemical vapor deposition) as is well known in the art. For example, alumina can be deposited on a substrate by using aluminum trichloride (AlCl₃), carbon monoxide (CO) and hydrogen (H₂), or by using aluminum tribromide (AlBr₃) and nitrogen monoxide (NO), as raw materials for CVD.

The etching gas used for etching the metal oxide comprises both a reducing gas and a reactive gas.

The reducing gas is capable of reducing a metal oxide to a corresponding metal, and is non-reactive with the metal formed by the reduction of the metal oxide. The reducing gas can be selected from methane (CH₄) gas, carbon monoxide (CO) gas, hydrogen (H₂) gas, and any combination of these gases. Since the reducing gas is non-reactive with the metal formed by the reduction, the metal is not subjected to any changes by the reducing gas. Methane reduces the metal oxide to form the metal, CO (or CO₂) and H₂O. Carbon monoxide reduces the metal oxide to form the metal and CO₂. Hydrogen reduces the metal oxide to form the metal and H₂O. Thus, all of the reaction products produced by the reduction with the reducing gas, except for the metal, are volatile. In other words, the reducing gas may be the one which is capable of reducing the metal oxide to form reaction products which are volatile under the reduced pressure at which the etching is conducted in the vacuum chamber, except for the metal formed by the reduction.

The reactive gas is capable of etching the metal formed by the reduction of the metal oxide with the reducing gas. In one embodiment of the present invention, the reactive gas comprises molecules containing chlorine atom as a constituent atom thereof. The reactive gas can be selected from chlorine (Cl₂) gas, hydrogen chloride (HCl) gas, boron trichloride (BCl₃) gas, and any combination of these gases. The chlorine gas reacts with the metal to produce a metal chloride. Hydrogen chloride gas reacts with the metal to produce a metal chloride and hydrogen gas. The boron trichloride behaves somewhat differently. The active chlorine ion species generated in the plasma from boron trichloride reacts with the metal to produce a metal chloride. On the other hand, the active boron ion species simultaneously generated in the plasma, being reductive in nature, reduce, together with the reducing gas, the metal oxide to a metal, and at the same time produce non-volatile boron oxide. However, the boron oxide thus formed is reduced to volatile boron by the reducing gas co-existing in the etching atmosphere. In this way, when BCl₃ is uses as a reactive gas, the reduction of metal oxide can be effected by both boron ion species and the reducing gas, shortening the time required for the reduction and hence the overall etching time.

To explain again, firstly the active reducing species derived from a reducing gas reduce a surface portion of the metal oxide film to the metal, and the reactive species derived from the reactive gas act on this metal to etch away the metal. A fresh surface of the residual metal oxide film exposed as a result of the etching is reduced by the active reducing species to the metal similarly, which in turn is etched away by the reactive species. In this way, the metal oxide film is etched.

As apparent from the above explanation, according to one embodiment of the present invention, overall reaction products generated upon etching the metal oxide film are volatile at least under a reduced pressure inside the vacuum chamber. Accordingly, all of these reaction products can be removed from the vacuum chamber by evacuation, and hence do not deposit on a substrate to lower the etching rate, and do not generate particles. Moreover, the etching rate, by the reactive gas species, of the metal reduced from the metal oxide is significantly higher than the etching rate of the metal oxide.

With respect to the ratio of flow rate ratio (volume ratio) of the reducing gas to the reactive gas, if the proportion of the reducing gas is excessively large relative to the reactive gas, the ratio of the reactive gas may become insufficient, making it difficult to perform the etching to a sufficient extent. Further, since the bonding force between the metal and oxygen in the metal oxide differs depending on the kinds of metal and since the reducing power of the reducing gas also differs depending on the kinds of reducing gas, it is difficult to indiscriminately determine an optimum flow rate ratio of the reducing gas to the reactive gas. Generally however, as long as the flow rate (volume) of the reducing gas is within the range of about 5 to about 30% of the total flow rate (volume) of the reducing gas and the reactive gas, it is possible to achieve a satisfactory etching rate of the metal oxide.

Although there is not any particular limitation with regard to the pressure inside the vacuum chamber at the etching, the inside pressure may range from about 5 to about 50 mTorr in general. The discharge voltage differs considerably depending on the configuration of etching apparatus employed. Needless to say, the discharge voltage should be sufficient to generate electric discharge.

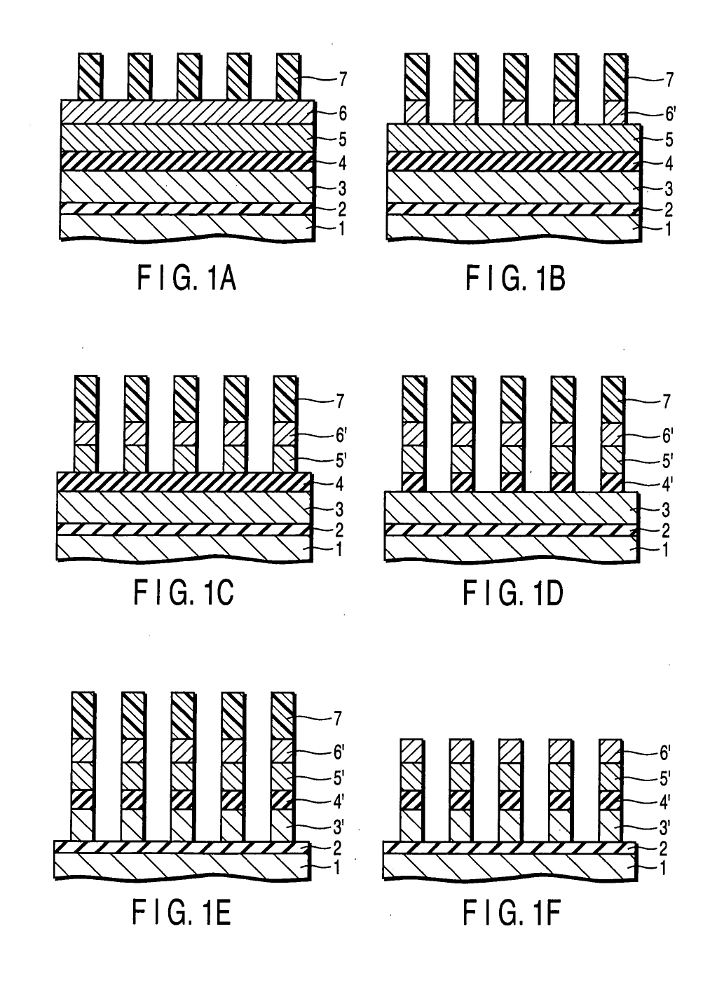

Next, with reference to FIGS. 1A to 1F, an example of forming a plurality (five in this example) of the gate electrode structures of NAND type non-volatile memory representing one example of semiconductor devices.

First, as shown in FIG. 1A, a common first gate insulating film 2 is formed on the surface of a silicon substrate 1. The gate insulating film 2 can be formed by thermal oxidation of the silicon substrate 1. Then, a film 3 of floating gate material, for example a polysilicon film, is deposited on the first gate insulating film 2 by CVD.

Further, a film 4 of high-k material providing a second gate insulating film is formed on the film 3 by CVD. As described above, the high-k material may be alumina (Al₂O₃), hafnium oxide (HfO₃), aluminum hafnium oxide (AlHfOₓ), or hafnium silicon oxide (HfSiOₓ).

Then, a film 5 of control gate material, for example a polysilicon film, is deposited on the film 4 by CVD. Thereafter, a film 6 for lowering the electric resistance of the control gate, for example a film of high-melting point metal silicide such as tungsten silicide, is deposited on the film 5 by CVD. Subsequently, a resist is applied on the film 6 and processed into a resist pattern 7 by photolithography technique. Incidentally, instead of the resist pattern, a hard mask formed from, e.g., silicon oxide or silicon nitride, can be used.

Thereafter, as shown in FIG. 1B, using the resist pattern 7 as a mask, the film 6 is etched by RIE using a chlorine-containing gas such as a gas containing Cl₂ or Cl₂/O₂, a gas containing CF₄/Cl₂, thereby forming an electric resistance-lowering film 6′.

Then, as shown in FIG. 1C, using the resist pattern 7 (together with the electric resistance-lowering film 6′) as a mask, the film 5 is etched by RIE using a mixed gas containing HBr and chlorine-containing molecule such as a gas containing HBr/Cl₂/O₂, thereby forming a control gate film 5′.

Subsequently, as shown in FIG. 1D, using the resist pattern 7 (together with the electric resistance-lowering film 6′ and the control gate film 5′) as a mask, the film 4 is etched by RIE using the etching gas comprising both the reducing gas and the reactive gas according to the aforementioned embodiment of the present invention, thereby forming a second gate insulating film 4′.

Following the etching of the film 4, as shown in FIG. 1E, using the resist pattern 7 (together with the electric resistance-lowering film 6′, the control gate film 5′ and the second gate insulating film 4′) as a mask, the film 3 is etched by RIE using a mixed gas containing HBr and chlorine-containing molecule such as a gas containing HBr/Cl₂/O₂, thereby forming a floating gate film 3′.

Subsequently, as shown in FIG. 1F, the resist pattern 7 is removed, thus providing gate electrode structures of an NAND type non-volatile memory.

A high-k material constituting the film 4 etched in the step of FIG. 1D, such as alumina (Al₂O₃), hafnium oxide (HfO₃), aluminum-hafnium oxide (AlHfOₓ) or hafnium-silicon oxide (HfSiOₓ), is a compound composed of metal and oxygen. Such metal oxide is strong in the bonding strength between the metal and the oxygen, so that a sufficiently high etching rate can not be obtained if the etching is performed using chlorine gas alone. To the contrary, when a mixture gas comprising both the reducing gas and the reactive gas is employed according to one embodiment of the present invention, a higher etching rate can be obtained as compared with the case where chlorine gas is employed alone.

### EXAMPLES

Experiments were conducted to investigate the etching rates of alumina as an example, when chlorine gas was employed alone as an etching gas according to the conventional method, and when a mixed gas of chlorine gas with methane gas was employed.

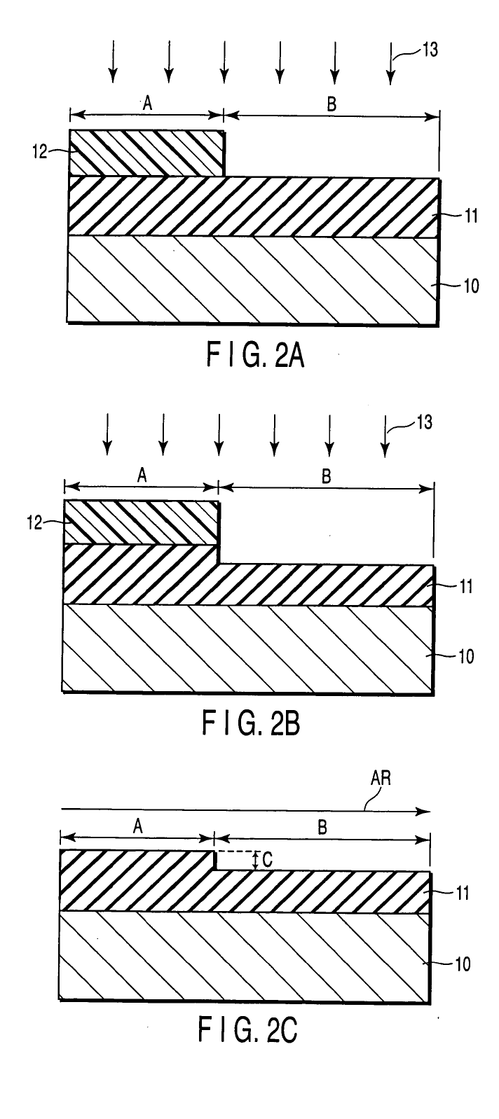

FIGS. 2A to 2C are cross-sectional views sequentially illustrating the procedures for these experiments.

As shown in FIG. 2A, an alumina film 11 is formed on a silicon substrate 10 by CVD, and a polyimide film 12 (KAPTON (registered trademark), Du Pont Co., Ltd.) is applied to cover a part of the alumina film 11. Thereafter, the silicon substrate 10 is subjected to etching gas plasma 13 by RIE.

Since the polyimide film 12 acts as a mask, the portion of the alumina film which is located at a region “A” where the alumina film 11 is covered by the polyimide film 12 is not etched, while the rest of the alumina film which is located at a region “B” where the alumina film 11 is exposed is etched, as shown in FIG. 2B.

After the etching, the polyimide film 12 formed at the region “A” was removed, as shown in FIG. 2C. As a result, a step “C” is formed on the surface of the alumina film 11, i.e., at the boundary between the region “A” and the region “B”. By measuring this step “C”, the etched depth can be determined.

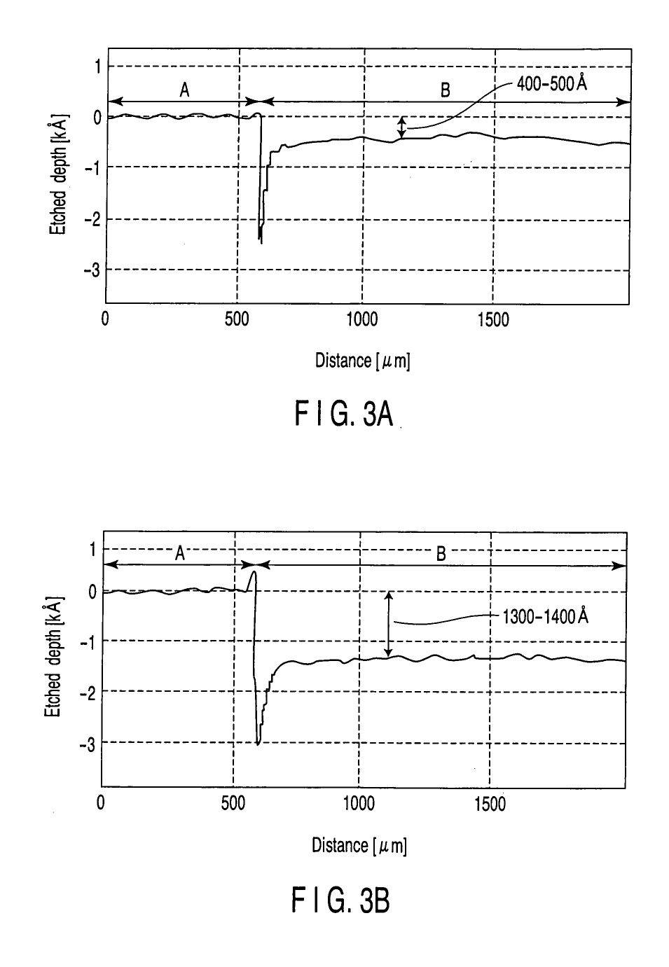

This step on the surface of the alumina film 11 was measured by a tracer method using a profilometer (Alpha-Step 200 (trade name), TENCOR Co., Ltd.) operated to move in the direction indicated by an arrow AR shown in FIG. 2C. The results are shown in FIGS. 3A and 3B. In FIGS. 3A and 3B, the abscissa denotes the distance in the direction of the arrow AR shown in FIG. 2C, and the ordinate denotes the etched depth (unit: kiloangstrom (kÅ)) of the alumina film 11. Further, in FIGS. 3A and 3B, “A” denotes a region where the alumina film 11 was covered with the polyimide film 12 and was not etched, while “B” denotes a region where the alumina film 11 was etched by RIE.

FIG. 3A shows the results of the experiment wherein the alumina film 11 was etched using chlorine (Cl₂) gas alone as an etching gas under the conditions that the flow rate of chlorine gas was 100 sccm, the pressure inside the vacuum chamber was 40 mTorr, the discharge electric power was 400 W, and the etching time was 300 sec.

On the other hand, FIG. 3B shows the results of the experiment wherein the alumina film 11 was etched using, as an etching gas, a mixed gas of chlorine gas with methane gas under the conditions that the flow rate ratio of the chlorine gas to the methane gas (Cl₂/CH₄) was 90 sccm/10 sccm, the pressure inside the vacuum chamber was 40 m Torr, the discharge electric power was 400 W, and the etching time was 300 sec.

It will be clear from the comparison in height of the steps “C” between the region “A” and the region “B” that while the height of the step “C” in FIG. 3A was about 400-500 angstroms, the height of the step “C” in FIG. 3B was about 1300-1400 angstroms. Thus, it will be clearly understood that when a mixed gas of chlorine gas with methane gas is employed as an etching gas, it is possible to considerably increase (by about three times) the etching rate of alumina film as compared with the etching rate obtained when chlorine gas is employed alone.

This is the phenomenon presented due to the fact that the bonding strength between aluminum and oxygen atom is very strong in alumina. Alumina, if remaining as such, reacts with chlorine ion species only slowly, and hence the etching rate of alumina is slow.

However, when a mixed gas of chlorine gas with methane gas is employed as an etching gas, firstly the surface of alumina film is reduced to aluminum by the methane gas. The reaction formula is:
Al₂O₃+CH₄→Al+CO (or CO₂)+H₂O

Since chlorine ions are significantly high in the rate of reaction with aluminum (the reaction takes place readily) compared with the rate of reaction with alumina, aluminum can be etched within a shorter period of time. The reaction formula is:
Al+Cl₂→AlCl₃

When aluminum on the surface portion of the alumina film is etched in this manner to expose a new surface portion of alumina film, the exposed new alumina portion is reduced by the methane gas again to expose aluminum thus reduced. Under the circumstances, the chlorine ions can always etch aluminum, enhancing the etching rate of alumina.

In this manner, by using a mixed gas containing the reactive gas and the reducing gas, as an etching gas, the alumina film 11 can be etched to a desired depth within a shorter period of time as compared with the case where chlorine gas is employed alone according to the conventional method.

Therefore, other films such as tungsten silicide film 6 and control gate film 5 are not exposed to the etching gas plasma for a long period of time during the etching of the alumina film 4 in the formation of the gate electrode structures of the NAND type non-volatile memory described with reference to FIG. 1D. Thus, such other films can be prevented from being deteriorated in the step of etching the alumina film 4.

Moreover, the volatile reaction products produced in the reduction of the alumina film 4 as well as in the etching of aluminum can be exhausted in the form of gas and thus do not deposit on the surface of a semiconductor substrate, giving no damages to the substrate.

When a mixed gas of carbon monoxide with boron trichloride was employed as an etching gas in the above experiments, results similar to those shown in FIG. 3B were obtained.

In the foregoing, the formation of the gate electrode structures of the NAND type non-volatile memory is explained as one example, but the present invention should not be limited thereto and can be applied to the manufacture of other semiconductor devices involving etching of metal oxide film. It is needless to say, two or more of the various embodiments described above may be combined.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A method of manufacturing a semiconductor device, which comprises etching a film of a metal oxide comprising a metal bonded with oxygen, formed above a semiconductor substrate, by using an etching gas, the etching gas comprising a reducing gas which is capable of reducing the metal oxide and is non-reactive with the metal, and a reactive gas which is capable of etching the metal.

2. The method according to claim 1, wherein the etching is performed in a vacuum chamber by a reactive ion etching method.

3. The method according to claim 1, wherein the reducing gas in the etching gas occupies about 5 to about 30% of a total volume of the reducing gas and the reactive gas.

4. The method according to claim 1, wherein the etching is performed under a reduced pressure of about 5 to about 50 mTorr.

5. The method according to claim 4, wherein the etching produces overall reaction products which are volatile under the reduced pressure.

6. The method according to claim 1, wherein the metal oxide is selected from the group consisting of alumina, hafnium oxide, aluminum-hafnium oxide and hafnium-silicon oxide.

7. The method according to claim 1, wherein the reactive gas comprises a molecule containing, as a constituent element, chlorine atom.

8. The method according to claim 7, wherein the reactive gas comprises at least one gas selected from the group consisting of chlorine gas, hydrogen chloride gas and boron trichloride gas.

9. The method according to claim 1, wherein the reducing gas comprises at least one gas selected from the group consisting of methane gas, carbon monoxide gas and hydrogen gas.

10. The method according to claim 1, wherein the metal oxide film is covered with a first film structure having at least one through-hole partially exposing a surface of the metal oxide film.

11. The method according to claim 10, wherein the first film structure comprises a film of control gate material.

12. The method according to claim 10, wherein a second film structure is formed below the metal oxide film.

13. The method according to claim 12, wherein the second film structure comprises a film of floating gate material.

14. The method according to claim 1, wherein the reactive gas is boron trichloride gas, and the boron of the boron trichloride, together with the reducing gas, reduces the metal oxide.

15. The method according to claim 14, wherein the reducing gas reduces an oxide of the boron produced in the reduction of the metal oxide.

16. A method of manufacturing a semiconductor device, which comprises etching a film of a metal oxide comprising a metal bonded with oxygen, formed above a semiconductor substrate, by using an etching gas, the etching gas comprising a reducing gas which is capable of reducing the metal oxide to produce reaction products which are volatile under a reduced pressure, except for the metal, and a reactive gas which is capable of etching the metal.

17. The method according to claim 16, wherein the etching is performed in a vacuum chamber by a reactive ion etching method.

18. The method according to claim 16, wherein the reducing gas in the etching gas occupies about 5 to about 30% of a total volume of the reducing gas and the reactive gas.

19. The method according to claim 16, wherein the etching is performed under a reduced pressure of about 5 to about 50 mTorr.

20. The method according to claim 16, wherein the metal oxide is selected from the group consisting of alumina, hafnium oxide, aluminum-hafnium oxide and hafnium-silicon oxide.
